(19) United States
(12) Patent Application Publication
(10) Pub. No.: US 2013/0122685 A1
(43) Pub. Date: May 16, 2013

(54) Method of Manufacturing a Semiconductor Device

(71) Applicant: Eun-jung Kim, Daegu (KR)

(72) Inventor: Eun-jung Kim, Daegu (KR)

(73) Assignee: Samsung Electronics Co., Ltd.

(21) Appl. No.: 13/608,831

(22) Filed: Sep. 10, 2012

(30) Foreign Application Priority Data
Nov. 16, 2011 (KR) 10-2011-0119779

(51) Int. Cl. H01L 21/762; H01L 21/768; H01L 21/283

(52) U.S. Cl. 438/424; 438/589; 438/666; 257/E21.546; 257/E21.159; 257/E21.585

(57) ABSTRACT

A method of manufacturing a semiconductor device, the method including: forming a plurality of first trenches extending in one direction in at least a part of a substrate; forming a plurality of first filling layers for filling the plurality of first trenches and having protrusion portions extended from the substrate from the plurality of first trenches; forming spacers on side walls of the protrusion portions of the plurality of first filling layers so that a part of the substrate is exposed between the plurality of first filling layers; and forming a plurality of second trenches extending in parallel to the plurality of first trenches by etching the substrate exposed through the spacers.

### CROSS-REFERENCE TO RELATED APPLICATIONS

This application claims the benefit of Korean Patent Application No. 10-2011-0119779, filed on Nov. 16, 2011, in the Korean Intellectual Property Office, the disclosure of which is incorporated herein in its entirety by reference.

### BACKGROUND

The inventive concept relates to a method of manufacturing a semiconductor device, and, more particularly, to a method of manufacturing a semiconductor device having a trench structure.

As a size of a semiconductor apparatus becomes smaller, high capacity data processing may be necessary. Accordingly, it may be necessary to increase integration of a semiconductor device included in the semiconductor apparatus and form fine patterns in the semiconductor apparatus. Therefore, fine patterns having fine widths and intervals exceeding a resolution limitation of a photolithography process may be required.

### SUMMARY

The inventive concept provides a method of manufacturing a semiconductor device having improved reliability.

According to an aspect of the inventive concept, there is provided a method of manufacturing a semiconductor device, the method including forming a plurality of first trenches extending in one direction in at least a part of a substrate; forming a plurality of first filling layers for filling the plurality of first trenches and having protrusion portions extended from the substrate from the plurality of first trenches; forming spacers on side walls of the protrusion portions of the plurality of first filling layers so that a part of the substrate is exposed between the plurality of first filling layers; and forming a plurality of second trenches extending in parallel to the plurality of first trenches by etching the substrate exposed through the spacers.

The plurality of first trenches and the plurality of second trenches may be spaced apart from each other by constant distances and are alternately formed.

The forming of the plurality of first filling layers may include: filling the plurality of first trenches with first filling layer materials; and removing a top portion of the substrate by a predetermined thickness so that the side walls of the protrusion portions are exposed.

The method may further include: before forming the plurality of first trenches, forming a mold layer including a plurality of openings on the substrate, wherein the forming of the first trenches includes: etching the substrate by using the mold layer as an etch mask.

The forming of the plurality of first filling layers may include: filling the plurality of first trenches and the plurality of openings with first filling layer materials; and exposing the side walls of the protrusion portions by removing the mold layer.

The method may further include: forming a plurality of second filling layers for filling the plurality of second trenches; and planarizing the plurality of first filling layers and the plurality of second filling layers so that the substrate is exposed between the plurality of first filling layers and the plurality of second filling layers.

The plurality of first filling layers and the plurality of second filling layers may be device isolation layers formed of insulation materials.

At least one of the plurality of first filling layers and the plurality of second filling layers may include buried gates formed of conductive materials.

At least one of the plurality of first filling layers and the plurality of second filling layers may include buried bit lines formed of conductive materials.

The substrate may include a cell region in which the plurality of first trenches and the plurality of second trenches are formed and a peripheral circuit region surrounding the cell region, the method further include: before forming the plurality of second trenches, forming a mask pattern used to expose the cell region on the peripheral circuit region.

The mask pattern may be formed using a photolithography method.

The forming of the spacers may include: forming a spacer material layer covering the substrate and the protrusion portions; and etching a part of the spacer material layer so that the substrate is exposed between the plurality of first filling layers, wherein the forming of the mask pattern includes: forming a sacrificial mask layer covering the spacer material layer on the substrate; removing a part of the sacrificial mask layer so that a thickness of the sacrificial mask layer remaining between the protrusion portions of the cell region is greater than that of the sacrificial mask layer remaining in the peripheral circuit region; forming a mask layer on the substrate on which the sacrificial mask layer remains; and removing a part of the mask layer so that the mask layer remains only in the peripheral circuit region.

The sacrificial mask layer remaining in the cell region may be removed before etching the part of the spacer material layer.

The forming of the spacers may include: forming a spacer material layer covering the substrate and the protrusion portions; and etching a part of the spacer material layer so that the substrate is exposed between the plurality of first filling layers, wherein the forming of the mask pattern includes: forming a mask layer on the spacer material layer so that voids defined by the spacer material layer and the mask layer are formed between the protrusion portions; and removing a part of the mask layer so that the mask layer remains only in the peripheral circuit region.

According to another aspect of the inventive concept, there is provided a method of manufacturing a semiconductor device, the method including method of manufacturing a semiconductor device, the method include: forming a plurality of first trenches extending in one direction in at least a part of a substrate; forming a plurality of first filling layers for filling the plurality of first trenches; removing a top portion of the substrate by a predetermined thickness so that parts of the plurality of first filling layers are exposed, the exposed parts of the plurality of first filling layers comprising protrusion portions of the plurality of first filling layers that extend from the substrate; forming spacers on side walls of the protrusion portions of the plurality of first filling layers; forming a plurality of second trenches extending in parallel to the plurality of first trenches by etching the substrate exposed through the spacers; and forming a plurality of second filling layers for filling the plurality of second trenches.

### BRIEF DESCRIPTION OF THE DRAWINGS

Exemplary embodiments of the inventive concept will be more clearly understood from the following detailed description taken in conjunction with the accompanying drawings in which:

FIG. 1 is a schematic plan view of a semiconductor device according to an embodiment of the inventive concept;

FIGS. 2A and 2B respectively are a plan view and a cross-sectional view of a semiconductor device according to an embodiment of the inventive concept;

FIGS. 3A through 3I are cross-sectional views for describing a method of manufacturing a semiconductor device based on a processing sequence, according to an embodiment of the inventive concept;

FIGS. 4A through 4D are cross-sectional views for describing a method of manufacturing a semiconductor device based on a processing sequence, according to another embodiment of the inventive concept;

FIGS. 5A through 5E are cross-sectional views for describing a method of manufacturing a semiconductor device based on a processing sequence, according to another embodiment of the inventive concept;

FIGS. 6A and 6B are cross-sectional views for describing a method of manufacturing a semiconductor device based on a processing sequence, according to another embodiment of the inventive concept;

FIG. 7 is a cross-sectional view of a semiconductor device according to embodiments of the inventive concept; and

FIG. 8 is a cross-sectional view of a semiconductor device according to further embodiments of the inventive concept.

### DETAILED DESCRIPTION OF THE EMBODIMENTS

The inventive concept will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those of ordinary skill in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled with” another element or layer, it can be directly on, connected to or coupled with the other element or layer or intervening elements or layers may be present. In contrast, when an element is referred to as being “directly on,” “directly connected to” or “directly coupled with” another element or layer, there are no intervening elements or layers present. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments of the inventive concept are described herein with reference to cross-section illustrations that are schematic illustrations of idealized embodiments of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the inventive concept.

The same reference numerals are used to denote the same component throughout the specification. Thus, even if not mentioned or described in the corresponding drawing, the same reference numerals or similar reference numerals may be described with reference to other drawings. Also, even if no reference is used to denote a component, the component may be described with reference to other drawings.

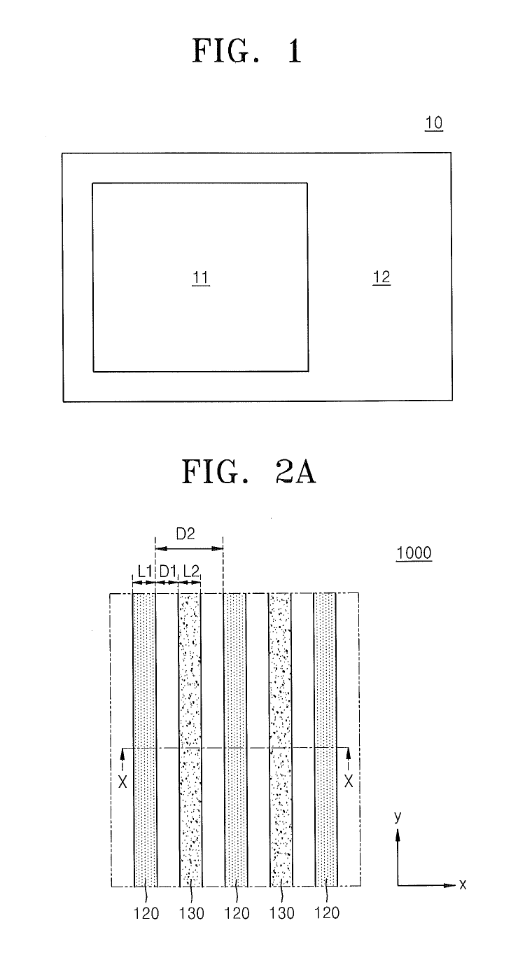

FIG. 1 is a schematic plan view of a semiconductor device 10 according to an embodiment of the inventive concept.

Referring to FIG. 1, the semiconductor device 10 includes a cell region 11 and a peripheral circuit region 12. In the cell region 11, a semiconductor memory cell array, for example, a volatile memory cell array like a DRAM or a non-volatile memory cell array like a flash memory may be formed. In the peripheral circuit region 12, peripheral circuits electrically connected to cell arrays formed in the cell region 11 may be formed. The peripheral circuit region 12 may also include a region like a core region in which no cell array is formed.

Although the cell region 11 is disposed in the center of the semiconductor device 10 and the peripheral circuit region 12 surrounds the cell region 11 in FIG. 1, the inventive concept is not limited thereto. The cell region 11 and the peripheral circuit region 12 may be optionally disposed appropriately. In another embodiment, a part of the peripheral circuit region 12 may be disposed inside the cell region 11.

The cell region 11 and the peripheral circuit region 12 may include transistors and device isolation layers having different sizes. In this case, to form uniform transistors and device isolation layers, the cell region 11 and the peripheral circuit region 12 may have transistors and device isolation layers formed therein by performing different processes.

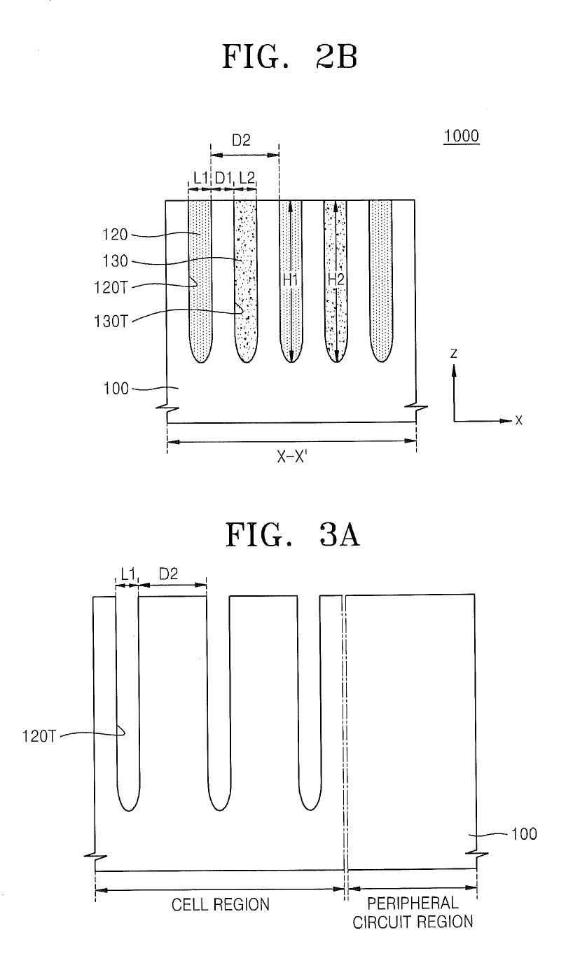

FIGS. 2A and 2B are a plan view and a cross-sectional view, respectively, of a semiconductor device 1000 according to an embodiment of the inventive concept.

The cross-sectional view of FIG. 2B corresponds to a line X-X′ of FIG. 2A. A structure of the semiconductor device 1000 of FIGS. 2A and 2B may be applied to the cell region 11 of FIG. 1.

Referring to FIGS. 2A and 2B, the semiconductor device 1000 includes a plurality of first device isolation layers 120 and a plurality of second device isolation layers 130 formed in a substrate 100.

The substrate 100 may be formed of a semiconductor, for example, silicon or silicon-germanium, and include an epitaxial layer, a silicon on insulator (SOI) layer, or a semiconductor on insulator (SeOI) layer.

The first device isolation layers 120 and the second device isolation layers 130 may be formed of insulation materials that are filled in first device isolation trenches 120T and second device isolation trenches 130T, respectively. The insulation materials may include, for example, oxide, nitride, or a combination of these materials.

The first device isolation layers 120 and the second device isolation layers 130 may have line shapes extending in one direction, for example, a y direction. The first device isolation layers 120 and the second device isolation layers 130 may be alternately disposed in one direction, for example, an x direction.

The first device isolation layers 120 may have first lengths L1 in the x direction. The first lengths L1 may be equal to second lengths L2 of the second device isolation layers 130. The first device isolation layers 120 may be spaced apart from the neighboring second device isolation layers 130 by first space distances D1. The neighboring first device isolation layers 120 may be spaced apart from each other by second space distances D2. The second space distances D2 may be, for example, three times the first space distances D1. For example, the first lengths L1, the second lengths L2, and the first space distances D1 may be equal to one another. However, the inventive concept is not limited thereto. The first lengths L1, the second lengths L2, and the first space distances D1 may be modified in various ways.

The first device isolation layers 120 may have first depths H1 from a top surface of the substrate 100 to a bottom surface thereof. The first depths H1 may be equal to second depths H2 from the top surface of the substrate 100 to bottom surfaces of the second device isolation layers 130. In another embodiment, the first depths H1 may be different from the second depths H2.

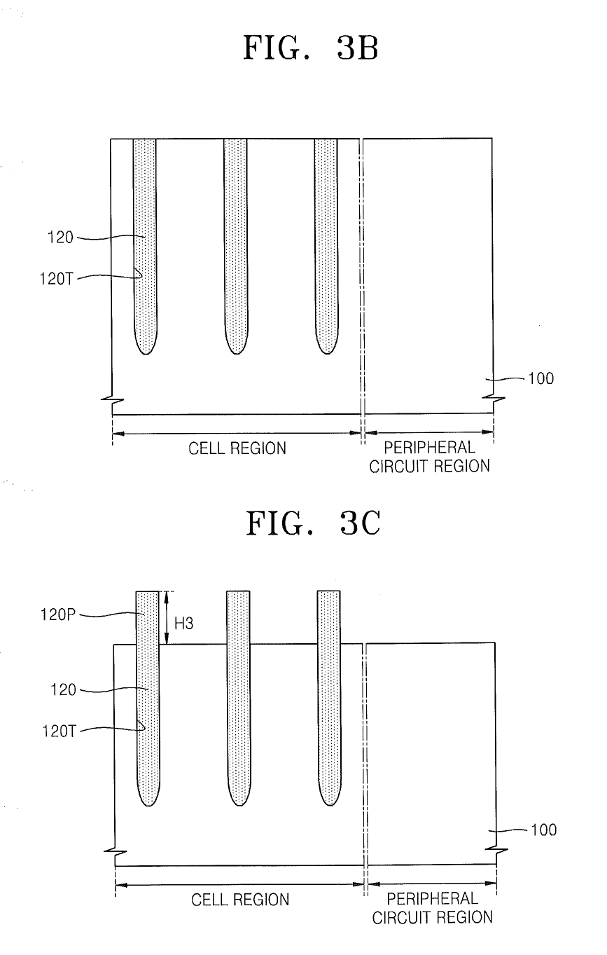

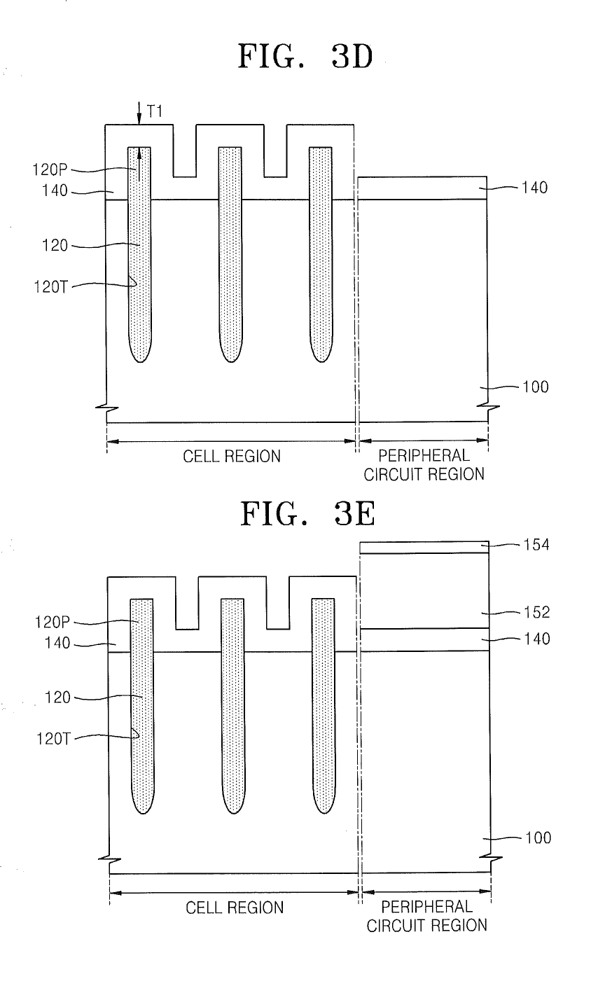

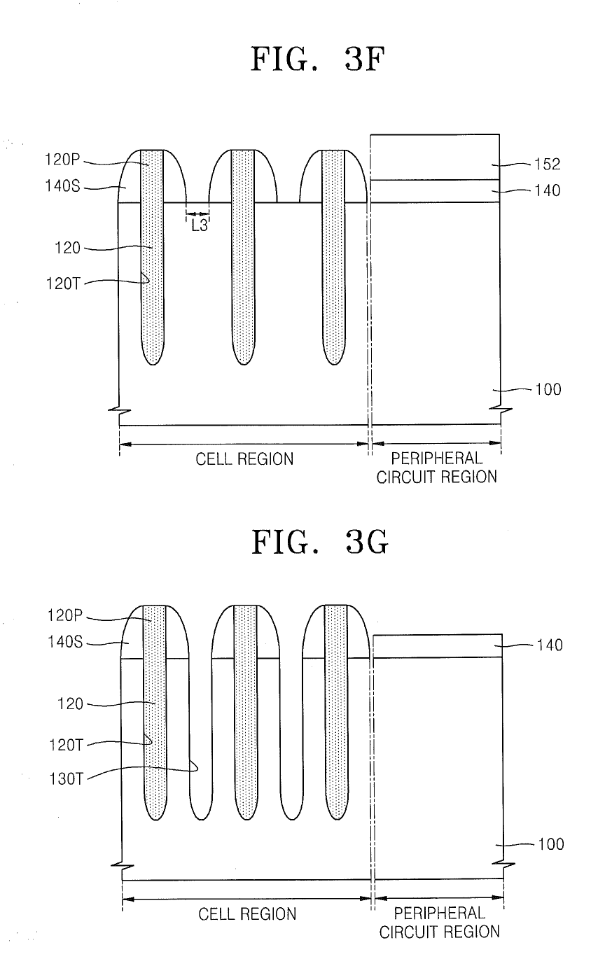

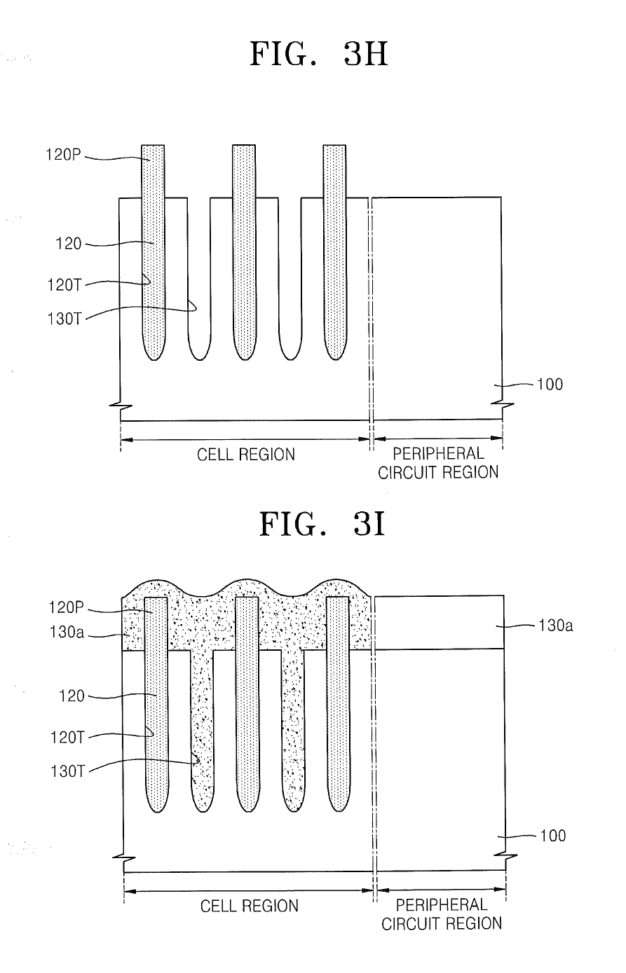

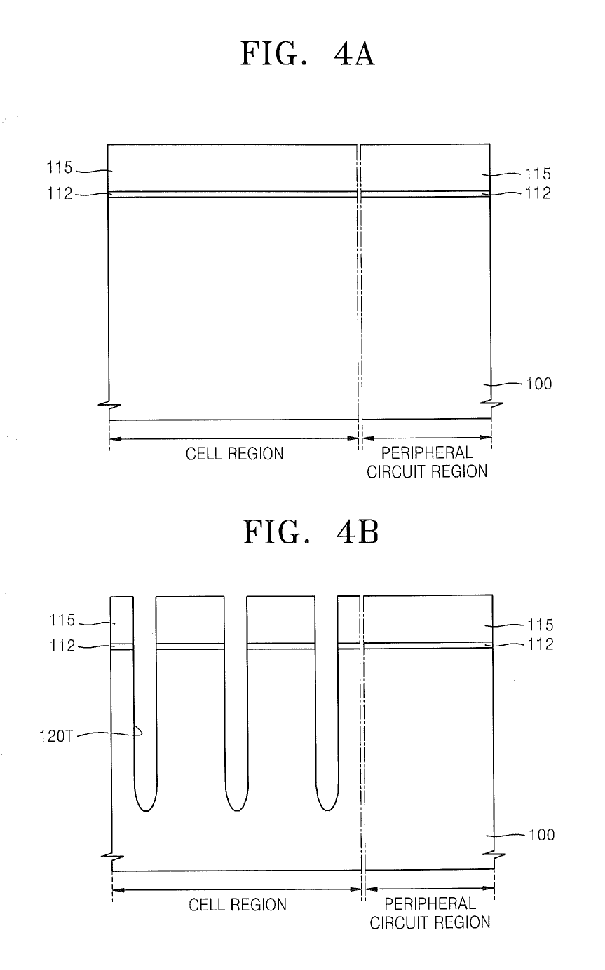

The first device isolation layers 120 may be formed by performing a shallow trench isolation (STI) process. The second device isolation layers 130 may be aligned by forming the second device isolation trenches 130T so that the second device isolation layers 130 may be self-aligned by the first device isolation layers 120 at both sides of the first device isolation layers 120. The method of forming the second device isolation layers 130 will be described in detail with reference to FIGS. 3A through 6B below.

The semiconductor device 1000 of the present embodiment is configured to self-align the second device isolation layers 130 by the first device isolation layers 120, thereby uniformly forming deep trench patterns of fine sizes without leaning them.

FIGS. 3A through 3I are cross-sectional views for describing a method of manufacturing a semiconductor device, according to an embodiment of the inventive concept. In FIGS. 3A through 3I, reference numerals that are the same as those in FIGS. 2A and 2B denote the same elements, and thus redundant descriptions will be omitted here.

A cell region and a peripheral circuit region shown in FIGS. 3A through 3I correspond to the line X-X′ of FIG. 2A.

Referring to FIG. 3A, a process of forming the first device isolation trenches 120T in the substrate 100 is performed. Although not shown, the first device isolation trenches 120T may be formed by etching the substrate 100 using a mask patterned through a photolithography process. Such etching may be anisotropic etching, for example, plasma etching. After the first device isolation trenches 120T are formed, an ion implantation process for enhancing insulation characteristics may be additionally performed.

The first device isolation trenches 120T may have the first length L1 and extend in one direction. The first lengths L1 may be, for example, several nanometers to several tens nanometers. The first device isolation trenches 120T may be spaced apart from each other by the second space distances D2.

In the present process, the first device isolation trenches 120T may be formed only in the cell region, and the substrate 100 of the peripheral circuit region may be protected by the patterned mask.

Referring to FIG. 3B, the first device isolation layers 120 may be formed by depositing insulation materials in the first device isolation trenches 120T. The first device isolation layers 120 may be formed, for example, using chemical vapor deposition (CVD) or atomic layer deposition (ALD).

The first device isolation layers 120 may consist of oxide, nitride, or a combination of these. The first device isolation layers 120 may be composite layers including, for example, a buffer oxide layer, a trench liner nitride layer, and a filling oxide layer. Alternatively, the first device isolation layers 120 may be one of high temperature oxide (HTO), high density plasma (HDP) oxide, tetra ethyl ortho silicate (TEOS), boro-phospho-silicate glass (BPSG) or undoped silicate glass (USG). After the first device isolation layers 120 are formed, an annealing process for achieving a high density layer material may be additionally performed.

After the first device isolation layers 120 are formed, a planarization process may be performed to expose a top surface of the substrate 100. The planarization process may be, for example, a chemical mechanical polishing (CMP) process.

Referring to FIG. 3C, a process of removing a part of a top portion of the substrate is performed. The process may result in a selective removal of a material of the substrate 100. As a result of the process, the first device isolation layers 120 include protrusion portions 120P that are formed toward the substrate 100 and have predetermined heights H3.

The heights H3 may be used to determine heights of spacers 140S in an operation of forming the spacers 140S that will be described with reference to FIG. 3F. The heights H3 may be, for example, two times to five times the first lengths L1 of FIG. 3A.

Referring to FIG. 3D, a spacer material layer 140 that covers an exposed surface of the substrate 100 and the protrusion portions 120P of the first device isolation layers 120 is stacked. The spacer material layer 140 may be formed of a material having a high etch selection ratio or etch selectivity with respect to the substrate 100 and the first device isolation layers 120. The etch selectivity may be quantitatively expressed as a rate of an etch speed of one layer with respect to an etch speed of another layer. The spacer material layer 140 may be formed of, for example, silicon oxide or silicon nitride. For example, if the first device isolation layers 120 are oxide layers, the spacer material layer 140 may be a silicon nitride layer. An ALD process may be used to form the spacer material layer 140 having a generally uniform thickness on the substrate 100.

A thickness T1 of the spacer material layer 140 may be used to determine sizes of the second device isolation trenches 130T in an operation of forming the second device isolation trenches 130T described with reference to FIG. 3G. In the present embodiment, the thickness T1 may be equal to the first lengths L1 (see FIG. 3A) of the first device isolation layers 120. In other embodiments, the thickness T1 may be smaller or greater than the first lengths L1.

Referring to FIG. 3E, a mask pattern 152 is formed in the peripheral circuit region. An anti-reflective layer 154 may be further formed on the mask pattern 152. The mask pattern 152 and the anti-reflective layer 154 may be formed to cover only the peripheral circuit region by a photolithography process.

The mask pattern 152 may be, for example, a hard mask layer including a carbon containing layer. For example, the mask pattern 152 may include a layer formed of a hydrocarbon compound or a derivative thereof having a comparatively high carbon content of about 85˜99 w % with respect to a total weight like an amorphous carbon layer (ACL) or a spin-on hardmask (SOH).

The anti-reflective layer 154 may reduce or prevent reflection during the photolithography process. The anti-reflective layer 154 may include an organic material or an inorganic material. For example, the anti-reflective layer 154 may include silicon oxynitride (SiON).

Referring to FIG. 3F, a process of forming the spacers 140S by removing a part of the spacer material layer 140 is performed. An etch-back process is performed to expose top surfaces of the first device isolation layers 120 and a part of the substrate 100 between the first device isolation layers 120, a part of the spacer material layer 140 is removed, and the spacers 140S are formed at both side walls of the first device isolation layers 120.

The spacers 140S may be used as etch masks for forming the second device isolation trenches 130T (see FIG. 3G) at a subsequent process. A third length L3 that is a length of the substrate 100 exposed by the spacers 140S may correspond to sizes of the second device isolation trenches 130T.

While the spacers 140S are etched, the anti-reflective layer 154 and the mask pattern 152 may be partially etched and removed. In another embodiment, the anti-reflective layer 154 may remain on the mask pattern 152.

Referring to FIG. 3G, a process of forming the second device isolation trenches 130T by etching the exposed substrate 100 using the spacers 140S as etch masks is performed.

During the etching process, the spacers 140S and the protrusion portions 120P may be partially etched and thus heights thereof may be reduced. Therefore, heights of the spacers 140S and the protrusion portions 120P may be determined at a preceding process as thicknesses that are possible to remain in consideration of thicknesses removed during the present etching process. For example, the greater the aspect ratio of the second device isolation trenches 130T, the greater the heights of the spacers 140S and the protrusion portions 120P.

Next, the mask pattern 152 of the peripheral circuit region may be removed. For example, if the mask pattern 152 is formed of a carbon containing material, the mask pattern 152 may be removed by performing an ashing process. In another embodiment, the mask pattern 152 may be removed simultaneously with the etching process of forming the second device isolation trenches 130T.

In the present process, the second device isolation trenches 130T are formed using the spacers 140S formed in side walls of the first device isolation layers 120, and thus the second device isolation trenches 130T may be spaced apart from the first device isolation layers 120 by generally uniform spacing. Also, in the embodiment of the inventive concept, the first device isolation trenches 120T and the second device isolation trenches 130T are separately formed, thereby reducing or preventing a defined trench pattern of the substrate 100 from leaning caused by simultaneously forming a plurality of trenches. Thus, deep fine trenches of small pitches may be formed.

Referring to FIG. 3H, the spacers 140S that remain in the cell region and the spacer material layer 140 that remains in the peripheral circuit region are removed by performing a selective removal process by wet etching.

Referring to FIG. 3I, an insulation material layer 130a for filling the second device isolation trenches 130T is deposited. The insulation material layer 130a may be formed of the same material as the first device isolation layers 120 described with reference to FIG. 3B. For example, the insulation material layer 130a may be formed of oxide, nitride, or a combination of these materials. In another embodiment, the insulation material layer 130a may be formed of a different material from the first device isolation layers 120. The insulation material layer 130a may be deposited using the same method as used in the first device isolation layers 120 described with reference to FIG. 3B. For example, the insulation material layer 130a may be formed using CVD or ALD.

Next, referring to FIGS. 2B and 3I, the insulation material layer 130a formed on the substrate 100 and the protrusion portions 120P of the first device isolation layers 120 may be removed so that the substrate 100 may be exposed between the first device isolation layers 120 and the second device isolation layers 130.

Accordingly, a structure in which the first device isolation layers 120 and the second device isolation layers 130 are alternately disposed is finally obtained as shown in FIG. 2B. The first device isolation layers 120 and the second device isolation layers 130 may have about the same widths and spaces. Also, the first device isolation layers 120 and the second device isolation layers 130 may be formed of the same materials. However, widths, positions, and types of materials of the first device isolation layers 120 and the second device isolation layers 130 are not limited thereto and may be modified in various ways.

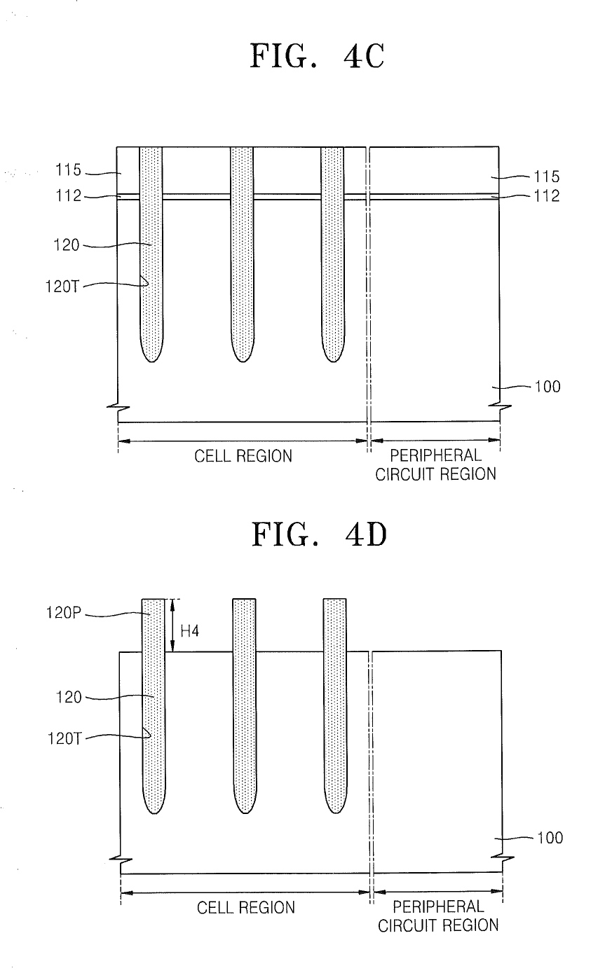

FIGS. 4A through 4D are cross-sectional views for describing a method of manufacturing a semiconductor device based on a processing sequence, according to another embodiment of the inventive concept. In FIGS. 4A through 4D, reference numerals that are the same as those in FIGS. 2A through 3I denote the same elements, and thus redundant descriptions will be omitted here.

A cell region and a peripheral circuit region shown in FIGS. 4A through 4D correspond to the line X-X′ of FIG. 2A.

Referring to FIG. 4A, a pad layer 112 and a mold layer 115 are sequentially stacked on the substrate 100. The pad layer 112 and the mold layer 115 may be formed using, for example, CVD.

The pad layer 112 may serve as a protective layer for the substrate 100, and may include, for example, a silicon oxide layer. In another embodiment, the pad layer 112 may be omitted.

The mold layer 115 may be used as a hard mask for forming the first device isolation trenches 120T (see FIG. 4B) in a subsequent process. The mold layer 115 may be formed of various layer materials according to a material of the substrate 100. For example, the mold layer 115 may be formed of one of silicon containing materials, such as silicon oxide (SiO₂), silicon nitride (Si₃N₄), and polysilicon.

Referring to FIG. 4B, a process of forming the first device isolation trenches 120T in the substrate 100 is performed. Although not shown, the first device isolation trenches 120T may be formed by etching the mold layer 115, the pad layer 112, and the substrate 100 using a mask patterned through a photolithography process. Such etching may be anisotropic etching, for example, plasma etching. The etching may be performed in situ or may be performed by dividing two or more operations on each of the mold layer 115, the pad layer 112, and the substrate 100.

The first device isolation trenches 120T may be spaced apart from each other by a predetermined distance and extend in one direction. In the present process, the first device isolation trenches 120T may be formed only in the cell region. As a result of the etching, the mold layer 115 includes openings that extend from the first device isolation trenches 120T in one direction and are spaced apart from each other by a predetermined distance like the first device isolation trenches 120T.

Referring to FIG. 4C, insulation materials are deposited inside of the first device isolation trenches 120T and openings of the mold layer 115. Thus, the first device isolation layers 120 may be formed. The first device isolation layers 120 may be formed using, for example, CVD or ALD.

The first device isolation layers 120 may be formed of oxide, nitride, or a combination of these materials. The first device isolation layers 120 may be composite layers including, for example, a buffer oxide layer, a trench liner nitride layer, and a filling oxide layer.

Referring to FIG. 4D, a process of selectively removing the mold layer 115 and the pad layer 112 of FIG. 4C may be performed so that the protrusion portions 120P may be formed on the substrate 100 by protruding parts of the first device isolation layers 120. Such a removal may be performed by, for example, wet etching. The removal may be performed in steps according to materials of the mold layer 115 and the pad layer 112. In another embodiment, the pad layer 112 may not be removed in the present process but may remain on the substrate 100.

Heights H4 of the protrusion portions 120P of the first device isolation layers 120 mainly depend on a thickness of the mold layer 115, and may be used to determine heights of the spacers 140S in a subsequent process of forming the spacers 140S (see FIG. 3F).

Next, the processes described with reference to FIGS. 3D through 3I are performed in the same way to form the semiconductor device 1000 of FIGS. 2A and 2B. In the present embodiment, without the process of removing the substrate 100 described with reference to FIG. 3C, the mold layer 115 may be used to manufacture the semiconductor device 1000 in the same way.

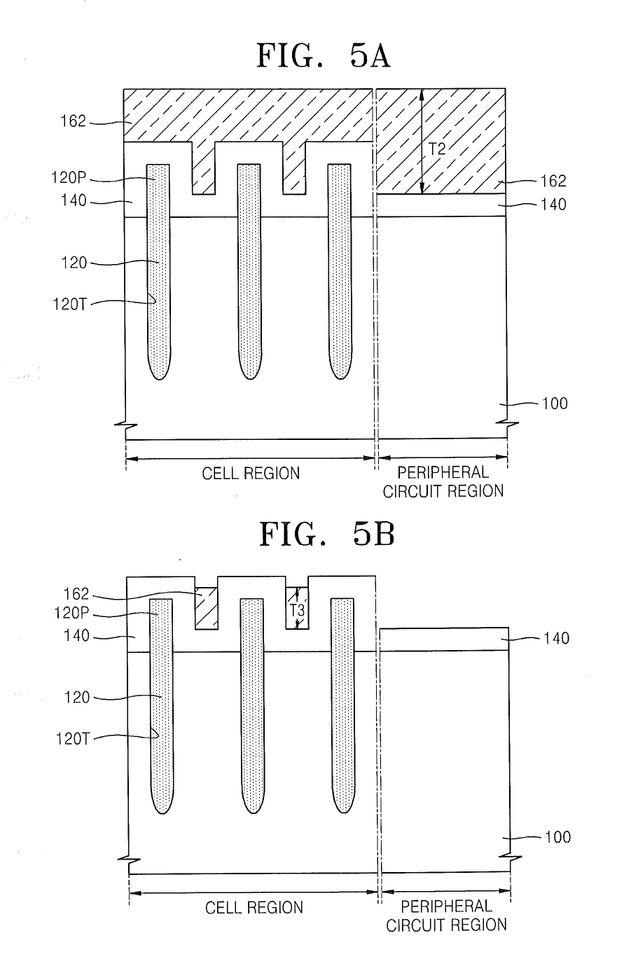

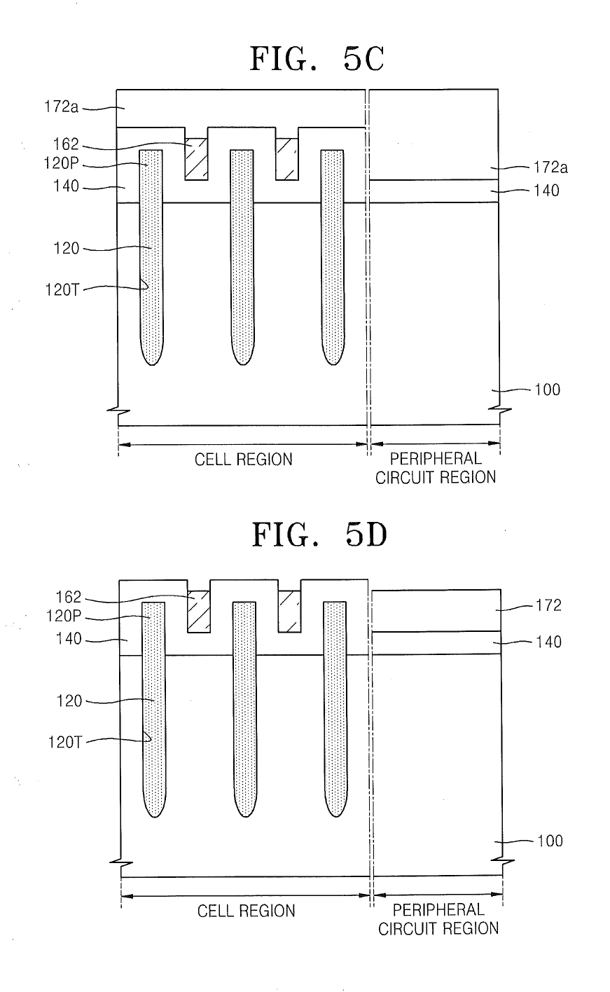

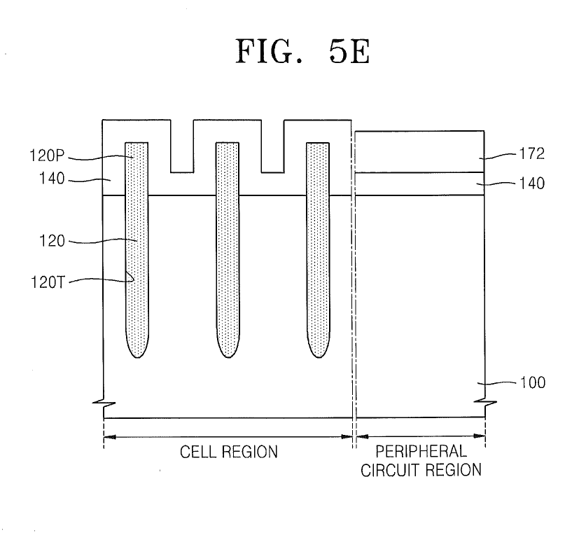

FIGS. 5A through 5E are cross-sectional views for describing a method of manufacturing a semiconductor device based on a processing sequence, according to another embodiment of the inventive concept. In FIGS. 5A through 5E, reference numerals that are the same as those in FIGS. 2A through 3I denote the same elements, and thus redundant descriptions will be omitted here.

A cell region and a peripheral circuit region shown in FIGS. 5A through 5E correspond to the line X-X′ of FIG. 2A.

Referring to FIG. 5A, the processes of forming the first device isolation layers 120 and the spacer material layer 140 described with reference to FIGS. 3A through 3D may be performed in the same way. Next, a sacrificial mask layer 162 having a predetermined thickness T2 may be formed. The thickness T2 may be a thickness enough for the sacrificial mask layer 162 to entirely fill a concave region formed in a top surface of the space material layer 140 and be stacked on the spacer material layer 140 between the protraction portions 120P of the neighboring first device isolation layers 120 of the cell region.

The sacrificial mask layer 162 may be formed of a material having a high etch selectivity with respect to the spacer material layer 140. For example, if the spacer material layer 140 is formed of silicon oxide or silicon nitride, the sacrificial mask layer 162 may be a carbon containing material. For example, the sacrificial mask layer 162 may be an SOH layer.

Referring to FIG. 5B, a process of removing a part of the sacrificial mask layer 162 is performed. The process may be, for example, an etch-back process. In the present process, the sacrificial mask layer 162 is removed from the spacer material layer 140 deposited to be planar in the peripheral circuit region, and the sacrificial mask layer 162 is removed from the spacer material layer 140 deposited to be winding in the cell region. Thus, a material used to remove the sacrificial mask layer 162, for example, an etching agent, and a reaction level of the sacrificial mask layer 162 may differ in the peripheral circuit region and the cell region.

Accordingly, the sacrificial mask layer 162 having the thickness T3 may remain in the concave region of the top surface of the spacer material layer 140 in the cell region, whereas the sacrificial mask layer 162 may not remain in the peripheral circuit region. In another embodiment, a thickness of the sacrificial mask layer 162 may be less than the thickness T3 in the peripheral circuit region.

Referring to FIG. 5C, a mask layer 172a may be formed on the sacrificial mask layer 162 and the spacer material layer 140 of the cell region and the spacer material layer 140 of the peripheral circuit region. The mask layer 172a may be formed of a material having a high etch selectivity with respect to the spacer material layer 140 and the sacrificial mask layer 162. For example, if the spacer material layer 140 is formed of silicon oxide or silicon nitride, and the sacrificial mask layer 162 is formed of a carbon containing material, the mask layer 172a may be silicon oxy-nitride (SiON).

Referring to FIG. 5D, a process of removing a part of the mask layer 172a of FIG. 5C is performed. The process may be, for example, an etch-back process. The process may be performed to entirely remove the mask layer 172a from the cell region and allow the mask layer 172a having a predetermined thickness to remain in the peripheral circuit region.

Accordingly, a mask pattern 172 covering the peripheral circuit region only is formed.

Referring to FIG. 5E, the sacrificial mask layer 162 remaining in the cell region is entirely removed. If the sacrificial mask layer 162 is a carbon containing material, the removal process may be an ashing process. Alternatively, the process may be a selective wet etching process.

Next, the processes described with reference to FIGS. 3F through 3I are performed in the same way to form the semiconductor device 1000 of FIGS. 2A and 2B. In the present embodiment, without a photolithography process, trenches may be formed only in the cell region by forming the mask pattern 172 on the peripheral circuit region.

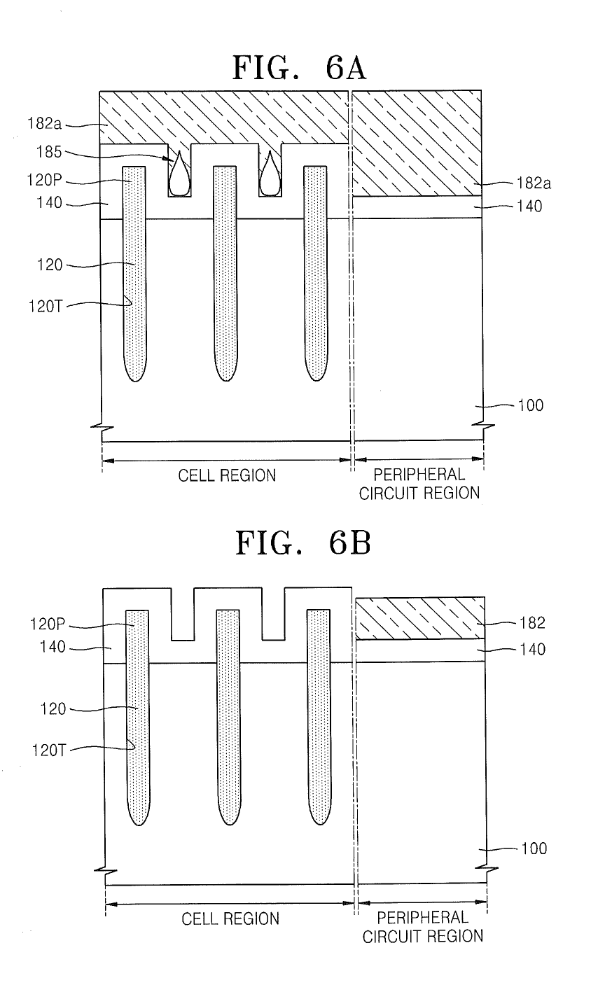

FIGS. 6A and 6B are cross-sectional views for describing a method of manufacturing a semiconductor device based on a processing sequence, according to another embodiment of the inventive concept. In FIGS. 6A and 6B, reference numerals that are the same as those in FIGS. 2A through 3I denote the same elements, and thus redundant descriptions will be omitted here.

A cell region and a peripheral circuit region shown in FIGS. 6A and 6B correspond to the line X-X′ of FIG. 2A.

Referring to FIG. 6A, the processes of forming the first device isolation layers 120 and the spacer material layer 140 described with reference to FIGS. 3A through 3D may be performed in the same way. Next, a mask layer 182a having a predetermined thickness may be formed.

The mask layer 182a may be formed of a material having a high etch selectivity with respect to the spacer material layer 140. The mask layer 182a may also be formed of a material that does not exhibit step coverage characteristics and conformality. For example, the mask layer 182a may be a tetra ethyl ortho silicate (TEOS) layer deposited using plasma. That is, a material that does not exhibit step coverage characteristics and conformality may be deposited in a non-uniform thickness in concave regions of a top surface of the spacer material layer 140 so that the mask layer 182a may not be deposited between the protrusion portions 120P. Thus, voids 185 defined by the spacer material layer 140 and the mask layer 182a may be formed between the protrusion portions 120P.

The shorter the second space distances D2 (see FIGS. 2A and 2B) between the first device isolation layers 120 and the higher the heights H3 (see FIG. 3C) of the protrusion portions 120P of the first device isolation layers 120 formed on the substrate 100, the more easily the voids 185 are formed. That is, the greater the aspect ratio of concave regions of the top surface of the spacer material layer 140 between the first device isolation layers 120, the more easily the voids 185 are formed. Shapes and sizes of the voids 185 are not limited to those of FIG. 6A.

In another embodiment, for example, if a semiconductor device having a small feature size is manufactured, the mask layer 182a may not be deposited on the spacer material layer 140 in the concave regions of the top surface of the spacer material layer 140. That is, the mask layer 182a may not exist in lower portions of the voids 185.

Referring to FIG. 6B, a process of removing a part of the mask layer 182a of FIG. 6A is performed. The process may be, for example, an etch-back process. During the process, the mask layer 182a of the cell region may be completely removed before the mask layer 182a of the peripheral circuit region. This is because a relatively small amount of a material of the mask layer 182a is removed from the cell region due to the voids 185 of FIG. 6A.

In the present process, a mask pattern 182 covering the peripheral circuit region only is formed.

Next, the processes described with reference to FIGS. 3F through 3I are performed in the same way to form the semiconductor device 1000 of FIGS. 2A and 2B. In the present embodiment, without a photolithography process, trenches may be formed only in the cell region by forming the mask pattern 182 on the peripheral circuit region.

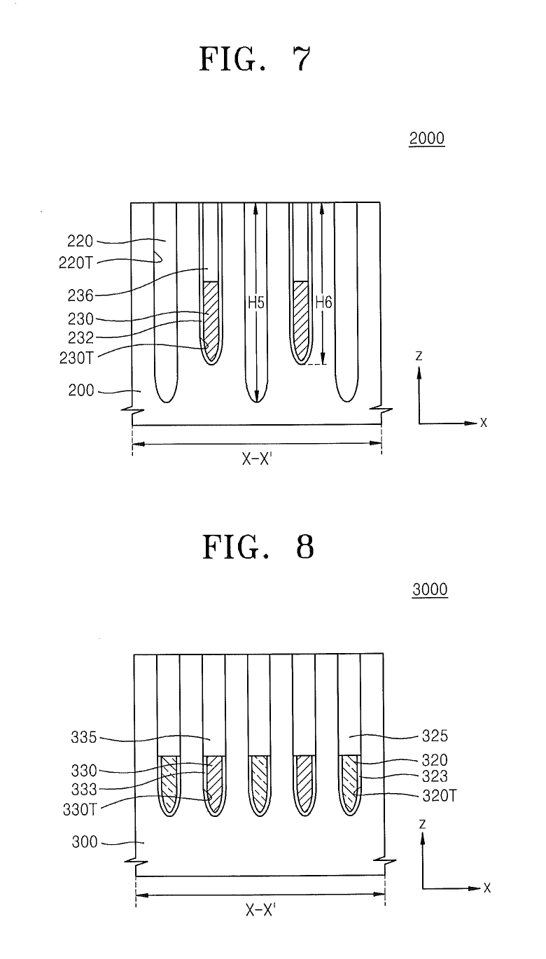

FIG. 7 is a cross-sectional view of a semiconductor device 2000 according to embodiments of the inventive concept.

A cell region and a peripheral circuit region shown in FIG. 7 correspond to the line X-X′ of FIG. 2A.

Referring to FIG. 7, the semiconductor device 2000 includes a plurality of device isolation layers 220 and a plurality of gate lines 230 formed on a substrate 200. The gate lines 230 may be buried word lines including buried channel array transistors (BCATs).

The substrate 200 may be formed of a semiconductor, for example, silicon or silicon-germanium, and include an epitaxial layer, an SOI layer, or an SeOI layer.

The device isolation layers 220 and the gate lines 230 may have line shapes extending in one direction perpendicular to an x direction in a z direction. The device isolation layers 220 and gate lines 230 may be alternately disposed in one direction, for example, an x direction.

The device isolation layers 220 formed in device isolation trenches 220T may be formed of insulation materials. The insulation materials may be, for example, oxide, nitride, or a combination of these materials.

Gate insulation layers 232, gate lines 230, and capping layers 236 may be disposed in gate trenches 230T. The gate insulation layers 232 may be formed in side walls of the gate trenches 230T. The gate lines 230 may be formed on the gate insulation layers 232 and have heights lower than a top surface of the substrate 200. The gate insulation layers 232 may be formed of oxide, nitride, and/or oxy-nitride. The gate insulation layers 232 may include, for example, a silicon oxide layer or an insulation layer having high permittivity. The gate lines 230 may be formed of metal, metal nitride, or doped polysilicon. For example, the gate lines 230 may be formed of titanium nitride (TiN). The capping layer 236 may cover top portions of the gate lines 230. The capping layer 236 may include, for example, a silicon nitride layer.

The device isolation layers 220 may have fifth heights H5 from the top surface of the substrate 200 to a bottom surface thereof. The fifth heights H5 may be greater than sixth heights H6 of the gate lines 230 from the top surface of the substrate 200 to bottom surfaces of the gate trenches 230T. However, the inventive concept is not limited thereto.

A method of forming the device isolation trenches 220T and the gate trenches 230T is similar to that of forming the semiconductor device described with reference to FIGS. 3A through 3H. That is, the device isolation trenches 220T and the gate trenches 230T may respectively correspond to one of the first device isolation trenches 120T and the second device isolation trenches 130T of FIGS. 3A through 3H, except that after the gate trenches 230T are formed, the gate insulation layers 232, the gate lines 230, and the capping layers 236 are sequentially formed.

According to the semiconductor device 2000 of the present embodiment, after forming and filling one of the device isolation trenches 220T and the gate trenches 230T, other elements are formed, thereby reducing or preventing a pattern defining trenches from leaning and forming deep fine trenches. Further, the gate trenches 230T are self-aligned in the device isolation trenches 220T or the device isolation trenches 220T are self-aligned in the gate trenches 230T, thereby reducing or preventing trenches from being misaligned.

FIG. 8 is a cross-sectional view of a semiconductor device 3000 according to embodiments of the inventive concept.

A cell region and a peripheral circuit region shown in FIG. 8 correspond to the line X-X′ of FIG. 2A.

Referring to FIG. 8, the semiconductor device 3000 includes a plurality of first bit lines 320 and a plurality of second bit lines 330 formed in a substrate 300.

The substrate 300 may be formed of a semiconductor, for example, silicon or silicon-germanium, and include an epitaxial layer, an SOI layer, or an SeOI layer.

The first bit lines 320 and the second bit lines 330 may have line shapes extending in one direction perpendicular to an x direction in a z direction. The first bit lines 320 and the second bit lines 330 may be alternately disposed in one direction, for example, an x direction. The first bit lines 320 and the second bit lines 330 may have the same structures and sizes.

In first bit line trenches 320T and second bit line trenches 330T, diffusion barrier layers 323 and 333 may be respectively disposed in bottom portions of the first bit lines 320 and the second bit lines 330, and active layers 325 and 335 may be respectively disposed in top portions thereof. The diffusion barrier layers 323 and 333 may act to reduce or prevent materials from diffusing between the first bit lines 320 and the second bit lines 330 and the substrate 300. The diffusion barrier layers 323 and 333 may include, for example, titanium nitride (TiN) layers. The active layers 325 and 335 may be formed of the same material as the substrate 300. The first bit lines 320 and the second bit lines 330 may include conductive materials, for example, metals like copper (Cu) or aluminum (Al).

The first bit lines 320 and the second bit lines 330 may be formed using a method similar to that of forming the semiconductor device described with reference to FIGS. 3A through 3H. That is, the first bit line trenches 320T and second bit line trenches 330T may respectively correspond to one of the first device isolation trenches 120T and the second device isolation trenches 130T of FIGS. 3A through 3H, except that after the first bit line trenches 320T and second bit line trenches 330T are formed, insulation materials are not filled therein, but the diffusion barrier layers 323 and 333, the first bit lines 320 or the second bit lines 330, and the active layers 325 and 335 are sequentially formed.

According to the semiconductor device 3000 of the present embodiment, after forming and filling one of the first bit line trenches 320T and the second bit line trenches 330T, other elements are formed, thereby reducing or preventing a pattern defining trenches from leaning and forming deep fine trenches. Further, the first bit line trenches 320T or the second bit line trenches 330T that are formed later are self-aligned in the first bit line trenches 320T or the second bit line trenches 330T that are formed earlier, thereby reducing or preventing trenches from being misaligned.

While the inventive concept has been particularly shown and described with reference to exemplary embodiments thereof, it will be understood that various changes in form and details may be made therein without departing from the spirit and scope of the following claims.

What is claimed is:

1. A method of manufacturing a semiconductor device, comprising:
forming a plurality of first trenches extending in one direction in at least a part of a substrate;
forming a plurality of first filling layers for filling the plurality of first trenches and having protrusion portions extended from the substrate from the plurality of first trenches;
forming spacers on side walls of the protrusion portions of the plurality of first filling layers so that a part of the substrate is exposed between the plurality of first filling layers; and
forming a plurality of second trenches extending in parallel to the plurality of first trenches by etching the substrate exposed through the spacers.

2. The method of claim 1, wherein the plurality of first trenches and the plurality of second trenches are spaced apart from each other by constant distances and are alternately formed.

3. The method of claim 1, wherein the forming of the plurality of first filling layers comprises:
filling the plurality of first trenches with first filling layer materials; and
removing a top portion of the substrate by a predetermined thickness so that the side walls of the protrusion portions are exposed.

4. The method of claim 1, further comprising: before forming the plurality of first trenches, forming a mold layer including a plurality of openings on the substrate,
wherein the forming of the first trenches comprises: etching the substrate by using the mold layer as an etch mask.

5. The method of claim 4, wherein the forming of the plurality of first filling layers comprises:
filling the plurality of first trenches and the plurality of openings with first filling layer materials; and
exposing the side walls of the protrusion portions by removing the mold layer.

6. The method of claim 1, further comprising:
forming a plurality of second filling layers for filling the plurality of second trenches; and
planarizing the plurality of first filling layers and the plurality of second filling layers so that the substrate is exposed between the plurality of first filling layers and the plurality of second filling layers.

7. The method of claim 6, wherein the plurality of first filling layers and the plurality of second filling layers are device isolation layers formed of insulation materials.

8. The method of claim 6, wherein at least one of the plurality of first filling layers and the plurality of second filling layers comprise buried gates formed of conductive materials.

9. The method of claim 6, wherein at least one of the plurality of first filling layers and the plurality of second filling layers comprise buried bit lines formed of conductive materials.

10. The method of claim 1, wherein the substrate comprises a cell region in which the plurality of first trenches and the plurality of second trenches are formed and a peripheral circuit region surrounding the cell region,
the method further comprises: before forming the plurality of second trenches, forming a mask pattern used to expose the cell region on the peripheral circuit region.

11. The method of claim 10, wherein the mask pattern is formed using a photolithography method.

12. The method of claim 10, wherein the forming of the spacers comprises:
forming a spacer material layer covering the substrate and the protrusion portions; and
etching a part of the spacer material layer so that the substrate is exposed between the plurality of first filling layers,
wherein the forming of the mask pattern comprises:
forming a sacrificial mask layer covering the spacer material layer on the substrate;
removing a part of the sacrificial mask layer so that a thickness of the sacrificial mask layer remaining between the protrusion portions of the cell region is greater than that of the sacrificial mask layer remaining in the peripheral circuit region;
forming a mask layer on the substrate on which the sacrificial mask layer remains; and
removing a part of the mask layer so that the mask layer remains only in the peripheral circuit region.

13. The method of claim 12, wherein the sacrificial mask layer remaining in the cell region is removed before etching the part of the spacer material layer.

14. The method of claim 10, wherein the forming of the spacers comprises:
forming a spacer material layer covering the substrate and the protrusion portions; and
etching a part of the spacer material layer so that the substrate is exposed between the plurality of first filling layers,
wherein the forming of the mask pattern comprises:
forming a mask layer on the spacer material layer so that voids defined by the spacer material layer and the mask layer are formed between the protrusion portions; and
removing a part of the mask layer so that the mask layer remains only in the peripheral circuit region.

15. A method of manufacturing a semiconductor device, comprising:
forming a plurality of first trenches extending in one direction in at least a part of a substrate;
forming a plurality of first filling layers for filling the plurality of first trenches;
removing a top portion of the substrate by a predetermined thickness so that parts of the plurality of first filling layers are exposed, the exposed parts of the plurality of first filling layers comprising protrusion portions of the plurality of first filling layers that extend from the substrate;
forming spacers on side walls of the protrusion portions of the plurality of first filling layers;
forming a plurality of second trenches extending in parallel to the plurality of first trenches by etching the substrate exposed through the spacers; and
forming a plurality of second filling layers for filling the plurality of second trenches.

16. A method of manufacturing a semiconductor device, comprising:
forming a plurality of first trenches in a substrate;
filing the plurality of first trenches with an insulating material, the insulating material including protrusion portions extending from each of the first trenches above an upper surface of the substrate, respectively;
forming spacers on sidewalls of the protrusion portions; and
forming a plurality of second trenches in the substrate using the spacers as an etching mask.

17. The method of claim 16, further comprising:
forming a mold layer on the substrate before forming the plurality of first trenches such that the plurality of first trenches are formed in the mold layer and the substrate; and
removing the mold layer after filling the plurality of first trenches with the insulating material so as to form the protrusion portions.

18. The method of claim 16, wherein the substrate comprises a cell region and a peripheral circuit region and the plurality of first trenches and the plurality of second trenches are formed in the cell region; and wherein forming the spacers comprises:
forming a spacer material layer on the substrate and the insulating material;
wherein the method further comprises:
forming a sacrificial mask layer on the spacer material layer and the substrate in the peripheral circuit region;
etching the sacrificial mask layer to remove a first portion of the sacrificial mask layer while leaving a second portion of the sacrificial mask layer between ones of the plurality of first trenches and to remove the sacrificial mask layer from the substrate in the peripheral circuit region;
forming a mask layer on the spacer material and the second portion of the sacrificial mask layer and on the substrate in the peripheral circuit region;
etching the mask layer to remove the mask layer from the spacer material layer and the second portion of the sacrificial mask layer while leaving a portion of the mask layer on the substrate in the peripheral circuit region; and
etching the spacer material layer to expose the substrate in the cell region and to form the spacers on the sidewalls of the protrusion portions.

19. The method of claim 16, wherein the substrate comprises a cell region and a peripheral circuit region and the plurality of first trenches and the plurality of second trenches are formed in the cell region; and wherein forming the spacers comprises:
forming a spacer material layer on the substrate and the insulating material;
forming a mask layer on the spacer material layer and on the substrate in the peripheral circuit region such that voids are formed in the mask layer between ones of the plurality of first trenches;
etching the mask layer to remove the mask layer from the spacer material layer while leaving a portion of the mask layer on the substrate in the peripheral circuit region; and
etching the spacer material layer to expose the substrate in the cell region and to form the spacers on the sidewalls of the protrusion portions.

20. The method of claim 19, wherein forming the mask layer comprises:
depositing a tetra ethyl ortho silicate layer using plasma.
